(19) United States
(12) Patent Application Publication
(10) Pub. No.: US 2017/0345524 A1
(43) Pub. Date: Nov. 30, 2017

(54) Roll Laminate, Method For Producing Roll Laminate, Method For Producing Laminate, Method For Producing Build-Up Substrate, Method For Producing Printed Wiring Board, And Method For Producing Electronic Device

(71) Applicant: JX Nippon Mining & Metals Corporation, Tokyo (JP)

(72) Inventor: Masayuki Takamori, Tokyo (JP)

(21) Appl. No.: 15/602,493

(22) Filed: May 23, 2017

(30) Foreign Application Priority Data
May 24, 2016 (JP) 2016-103755

(51) Int. Cl. H01B 5/14; H01B 13/00; B32B 15/20; B32B 15/04; B32B 15/01; H05K 3/10; B32B 7/12

(52) U.S. Cl. CPC H01B 5/14; H05K 3/10; H01B 13/0036; B32B 7/12; B32B 15/043; B32B 15/01; B32B 15/20

(57) ABSTRACT

Provided herein is a roll laminate that can desirably reduce scrapes on a metal foil surface even when a long metal foil is wound into a roll, and that can improve the productivity in use of the unwound roll metal foil. The roll laminate includes a long first metal foil and a long second metal foil that are bonded to each other via an adhesive layer, and are wound around a support. The adhesive layer has a thickness of 1 μm or more in at least a part of the layer, and is provided along the longitudinal direction of the first and the second metal foil in at least both edge portions in the width of an overlapping region of the first and the second metal foil viewed in plan.

### TECHNICAL FIELD

The present invention relates to a roll laminate, a method for producing a roll laminate, a method for producing a laminate, a method for producing a build-up substrate, a method for producing a printed wiring board, and a method for producing an electronic device.

A printed wiring board is typically formed through the process of bonding an insulating substrate to a copper foil to produce a copper-clad laminate, and etching a copper foil surface to form a conductor pattern. Metal foils such as a copper foil are used for the production of a printed wiring board.

In a traditional method of metal foil production, a metal foil is often rolled by being wound around a support. Here, the winding of the metal foil often involves meandering. Winding a meandering metal foil into a coil causes a misalignment on a wind-up reel. Such a misalignment causes metal foil layers to rub against each other, and scrapes the metal foil surface.

This problem is addressed in JP-A-2009-22998, which discloses a metal foil winder for successively winding a rolled metal foil into a coil around a wind-up reel. The winder includes an interleaving paper unwinding roll for unwinding the interleaving paper that becomes inserted between layers of the coiled metal foil. The interleaving paper roll is wider than the metal foil. With this configuration, JP-A-2009-22998 is intended to prevent scrapes on a metal foil even when a misalignment occurs as a result of meandering of the metal foil when successively winding a rolled metal foil into a coil around a wind-up reel, and improve the quality of the end product metal foil.

### CITATION LIST

### Patent Literature

PTL 1: JP-A-2009-22998

### SUMMARY OF INVENTION

### Technical Problem

However, the technique described in JP-A-2009-22998 involves the process of removing the interleaving paper when processing a roll of metal foil by unwinding it into a metal foil sheet. This is problematic in terms of production efficiency.

It is accordingly an object of the present invention to provide a roll laminate that can desirably reduce scrapes on a metal foil surface even when a long metal foil is wound into a roll, and that can improve the productivity in use of the unwound roll metal foil.

### Solution to Problem

The present inventors diligently worked to achieve the foregoing object, and found that scrapes on a metal foil surface can be desirably reduced even when a long metal foil is wound into a roll, and the productivity in use of the unwound roll metal foil can improve when long metal foils are bonded to each other with an adhesive layer of a predetermined thickness provided at predetermined locations, and are wound around a support to form a roll laminate.

The present invention was completed on the basis of this finding, and an aspect of the invention is a roll laminate comprising a long first metal foil and along second metal foil that are bonded to each other via an adhesive layer, and are wound around a support. The adhesive layer has a thickness of 1 μm or more in at least a part of the layer, and is provided along the longitudinal direction of the first and the second metal foil in at least both edge portions in the width of an overlapping region of the first and the second metal foil viewed in plan.

An embodiment of the roll laminate of the present invention is a roll laminate,

wherein the roll laminate does not fall into the following categories (A) to (C) of roll laminate:

(A) a roll laminate consisting of a structure in which:

only a first insulating layer and a first copper foil layer are provided in such order that the roll laminate has the first insulating layer on the surface of the first metal foil opposite the surface that is in contact with the second metal foil, and the first copper foil layer on the surface of the first insulating layer opposite the first metal foil, and

only a second insulating layer and a second copper foil layer are provided in such order that the roll laminate has the second insulating layer on the surface of the second metal foil opposite the surface that is in contact with the first metal foil, and the second copper foil layer on the surface of the second insulating layer opposite the surface that is in contact with the second metal foil;

(B) a roll laminate consisting of a structure in which:

only a first insulating layer, a first copper foil layer, and a via hole are provided, wherein the first insulating layer is provided on the surface of the first metal foil opposite the surface that is in contact with the second metal foil, the first copper foil layer is provided on the surface of the first insulating layer opposite the surface that is in contact with the first metal foil, and the via hole is provided through the first insulating layer and the first copper foil layer, and

only a second insulating layer, a second copper foil layer, and a via hole are provided, wherein the second insulating layer is provided on the surface of the second metal foil opposite the surface that is in contact with the first metal foil, the second copper foil layer is provided on the surface of the second insulating layer opposite the surface that is in contact with the second metal foil, and the via hole is provided through the second insulating layer and the second copper foil layer; and

(C) a roll laminate consisting of a structure in which:

only a first insulating layer, a first copper foil layer, a first metal layer, and a first via hole are provided, wherein the first insulating layer is provided on the surface of the first metal foil opposite the surface that is in contact with the second metal foil, the first copper foil layer is provided on the surface of the first insulating layer opposite the surface that is in contact with the first metal foil, the first via hole is provided through the first insulating layer and the first copper foil layer, and the first metal layer is provided on the surface of the first copper foil layer opposite the surface that is in contact with the first insulating layer, and in the first via hole, and

only a second insulating layer, a second copper foil layer, a second metal layer, and a second via hole are provided, wherein the second insulating layer is provided on the surface of the second metal foil opposite the surface that is in contact with the first metal foil, the second copper foil layer is provided on the surface of the second insulating layer opposite the surface that is in contact with the second metal foil, the second via hole is provided through the second insulating layer and the second copper foil layer, and the second metal layer is provided on the surface of the second copper foil layer opposite the surface that is in contact with the second insulating layer, and in the second via hole.

In an embodiment of the roll laminate of the present invention, the adhesive layer has a thickness of 300 μm or less.

In another embodiment of the roll laminate of the present invention, the adhesive layer has a width of 0.5 mm or more.

In yet another embodiment of the roll laminate of the present invention, the adhesive layer has a width of 100 mm or less.

In still another embodiment of the roll laminate of the present invention, the first metal foil and the second metal foil each have a thickness of 5 to 70 μm.

In yet another embodiment of the roll laminate of the present invention, the adhesive layer is provided either continuously or discontinuously along the longitudinal direction of the first and the second metal foil.

Another aspect of the present invention is a roll laminate comprising a long first metal foil and a long second metal foil that are bonded to each other via an adhesive layer, and are wound around a support,

wherein the adhesive layer has a thickness of 1 μm or more in at least a part of the layer, and is provided along the longitudinal direction of the first and the second metal foil in at least both edge portions in the width of an overlapping region of the first and the second metal foil viewed in plan, and

wherein the roll laminate satisfies the formula 0≦d≦0.1×r, where d is the maximum depth of a gap created between the outermost surface of the roll laminate in the thickness direction of the first and the second metal foil, and a straight line drawn to connect the apices of bumps present on the outermost surface of the roll laminate in positions corresponding to the adhesive layers at both edge portions in the width of the first and the second metal foil, and r is the roll thickness of the roll laminate.

In another embodiment of the roll laminate of the present invention, the roll laminate satisfies at least one of the following (1) to (5):

(1) the adhesive layer has a thickness of 300 μm or less;

(2) the adhesive layer has a width of 0.5 mm or more;

(3) the adhesive layer has a width of 100 mm or less;

(4) the first metal foil and the second metal foil each have a thickness of 5 to 70 μm; and

(5) the adhesive layer is provided either continuously or discontinuously along the longitudinal direction of the first and the second metal foil.

In yet another embodiment of the roll laminate of the present invention, the maximum depth (d) of the gap created between the straight line and the outermost surface of the roll laminate, and the roll thickness (r) of the roll laminate satisfy the formula 0≦d≦0.05×r.

In still another embodiment of the roll laminate of the present invention, the adhesive constituting the adhesive layer has a viscosity of 3×10⁶ mPa·s (25° C.) or less after 3 minutes from application.

In yet another embodiment of the roll laminate of the present invention, the adhesive constituting the adhesive layer has a viscosity of 1×10⁶ mPa·s (25° C.) or less after 3 minutes from application.

Still another aspect of the present invention is a roll laminate comprising a long first metal foil and a long second metal foil that are bonded to each other via an adhesive layer, and are wound around a support,

wherein the adhesive layer has a thickness of 1 μm or more in at least a part of the layer, and is provided along the longitudinal direction of the first and the second metal foil in at least both edge portions in the width of an overlapping region of the first and the second metal foil viewed in plan, and

wherein:

(a) the first metal foil or the second metal foil protrudes beyond the other at the both ends in the width of the roll laminate in a plan view of the first and the second metal foil;

(b) one of the first metal foil and the second metal foil protrudes beyond the other metal foil at one end of the roll laminate in the width direction, and the other metal foil protrudes beyond the other at the other end of the roll laminate in the width direction in a plan view of the first and the second metal foil; or

(c) one of the first metal foil and the second metal foil protrudes beyond the other metal foil at one end of the roll laminate in the width direction, and the first and the second metal foil have aligned end portions at the other end of the roll laminate in the width direction in a plan view of the first and the second metal foil.

In another embodiment of the roll laminate of the present invention, the roll laminate satisfies at least one of the following (1) to (9):

(1) the adhesive layer has a thickness of 300 μm or less;

(2) the adhesive layer has a width of 0.5 mm or more;

(3) the adhesive layer has a width of 100 mm or less;

(4) the first metal foil and the second metal foil each have a thickness of 5 to 70 μm;

(5) the adhesive layer is provided either continuously or discontinuously along the longitudinal direction of the first and the second metal foil;

(6) the roll laminate satisfies the formula 0≦d≦0.1×r, where d is the maximum depth of a gap created between the outermost surface of the roll laminate in the thickness direction of the first and the second metal foil, and a straight line drawn to connect the apices of bumps present on the outermost surface of the roll laminate in positions corresponding to the adhesive layers at both edge portions in the width of the first and the second metal foil, and r is the roll thickness of the roll laminate;

(7) the maximum depth (d) of the gap created between the straight line and the outermost surface of the roll laminate, and the roll thickness (r) of the roll laminate as defined in (6) satisfy the formula 0≦d≦0.05×r;

(8) the adhesive constituting the adhesive layer has a viscosity of 3×10⁶ mPa·s (25° C.) or less after 3 minutes from application; and

(9) the adhesive constituting the adhesive layer has a viscosity of 1×10⁶ mPa·s (25° C.) or less after 3 minutes from application.

Yet another aspect of the present invention is a roll laminate comprising a long first metal foil and a long second metal foil that are bonded to each other via an adhesive layer, and are wound around a support,

wherein the adhesive layer has a thickness of 1 μm or more in at least a part of the layer, and is provided along the longitudinal direction of the first and the second metal foil in at least both edge portions in the width of an overlapping region of the first and the second metal foil viewed in plan, and

wherein:

the first metal foil is a carrier for a carrier-attached metal foil that includes a carrier, an interlayer, and an ultrathin metal layer, in this order, and

the second metal foil is an ultrathin metal layer for another carrier-attached metal foil that includes a carrier, an interlayer, and an ultrathin metal layer, in this order.

Still another aspect of the present invention is a roll laminate comprising a long first metal foil and a long second metal foil that are bonded to each other via an adhesive layer, and are wound around a support,

wherein the adhesive layer has a thickness of 1 μm or more in at least a part of the layer, and is provided along the longitudinal direction of the first and the second metal foil in at least both edge portions in the width of an overlapping region of the first and the second metal foil viewed in plan, and

wherein the first metal foil and the second metal foil each comprise a carrier-attached metal foil that includes a carrier, an interlayer, and an ultrathin metal layer, in this order.

In yet another embodiment of the roll laminate of the present invention, the roll laminate satisfies at least one of the following (1) to (10):

(1) the adhesive layer has a thickness of 300 jam or less;

(2) the adhesive layer has a width of 0.5 mm or more;

(3) the adhesive layer has a width of 100 mm or less;

(4) the first metal foil and the second metal foil each have a thickness of 5 to 70 μm;

(5) the adhesive layer is provided either continuously or discontinuously along the longitudinal direction of the first and the second metal foil;

(6) the roll laminate satisfies the formula 0≦d≦0.1×r, where d is the maximum depth of a gap created between the outermost surface of the roll laminate in the thickness direction of the first and the second metal foil, and a straight line drawn to connect the apices of bumps present on the outermost surface of the roll laminate in positions corresponding to the adhesive layers at both edge portions in the width of the first and the second metal foil, and r is the roll thickness of the roll laminate;

(7) the maximum depth (d) of the gap created between the straight line and the outermost surface of the roll laminate, and the roll thickness (r) of the roll laminate as defined in (6) satisfy the formula 0≦d≦0.05×r;

(8) the adhesive constituting the adhesive layer has a viscosity of 3×10⁶ mPa·s (25° C.) or less after 3 minutes from application;

(9) the adhesive constituting the adhesive layer has a viscosity of 1×10⁶ mPa·s (25° C.) or less after 3 minutes from application; and

(10)

(a) the first metal foil or the second metal foil protrudes beyond the other at the both ends in the width of the roll laminate in a plan view of the first and the second metal foil,

(b) one of the first metal foil and the second metal foil protrudes beyond the other metal foil at one end of the roll laminate in the width direction, and the other metal foil protrudes beyond the other at the other end of the roll laminate in the width direction in a plan view of the first and the second metal foil, or

(c) one of the first metal foil and the second metal foil protrudes beyond the other metal foil at one end of the roll laminate in the width direction, and the first and the second metal foil have aligned end portions at the other end of the roll laminate in the width direction in a plan view of the first and the second metal foil.

Still another aspect of the present invention is a method for producing a roll laminate, the method comprising:

providing an adhesive layer along the longitudinal direction of a long first metal foil in both edge portions in the width of the long first metal foil;

bonding a long second metal foil to the adhesive layer-side surface of the first metal foil provided with the adhesive layer; and

winding around a support the long first metal foil and the long second metal foil that are bonded to each other via the adhesive layer.

Yet another aspect of the present invention is a method for producing a roll laminate,

the method comprising:

providing an adhesive layer along the longitudinal direction of a long first metal foil at both edge portions in the width of the first metal foil, wherein the first metal foil is not a metal foil that includes solely an insulating layer and a copper foil in this order on the surface opposite the surface provided with the adhesive layer;

bonding a long second metal foil to the adhesive layer-side surface of the first metal foil provided with the adhesive layer, wherein the second metal foil is not a metal foil that includes solely an insulating layer and a copper foil in this order on the surface opposite the surface bonded to the first metal foil; and

winding around a support the long first metal foil and the long second metal foil that are bonded to each other via the adhesive layer.

Still another aspect of the present invention is a method for producing a roll laminate,

the method comprising:

taking the first and the second metal foil from (i) a roll laminate comprising a long first metal foil and a long second metal foil that are bonded to each other via an adhesive layer, and are wound around a support, wherein the adhesive layer has a thickness of 1 μm or more in at least a part of the layer, and is provided along the longitudinal direction of the first and the second metal foil in at least both edge portions in the width of an overlapping region of the first and the second metal foil viewed in plan, or (ii) a roll laminate produced by the method of the present invention;

laminating a resin on at least one of the first metal foil and the second metal foil; and

winding the first metal foil, the second metal foil, and the resin around a support.

In an embodiment of the roll laminate producing method of the present invention, the build-up substrate producing method of the present invention, or the printed wiring board producing method of the present invention, the roll laminate satisfies at least one of the following (1) to (12):

(1) the adhesive layer has a thickness of 300 μm or less;

(2) the adhesive layer has a width of 0.5 mm or more;

(3) the adhesive layer has a width of 100 mm or less;

(4) the first metal foil and the second metal foil each have a thickness of 5 to 70 μm;

(5) the adhesive layer is provided either continuously or discontinuously along the longitudinal direction of the first and the second metal foil;

(6) the roll laminate satisfies the formula 0≦d≦0.1×r, where d is the maximum depth of a gap created between the outermost surface of the roll laminate in the thickness direction of the first and the second metal foil, and a straight line drawn to connect the apices of bumps present on the outermost surface of the roll laminate in positions corresponding to the adhesive layers at both edge portions in the width of the first and the second metal foil, and r is the roll thickness of the roll laminate;

(7) the maximum depth (d) of the gap created between the straight line and the outermost surface of the roll laminate, and the roll thickness (r) of the roll laminate as defined in (6) satisfy the formula 0≦d≦0.05×r;

(8) the adhesive constituting the adhesive layer has a viscosity of 3×10⁶ mPa·s (25° C.) or less after 3 minutes from application;

(9) the adhesive constituting the adhesive layer has a viscosity of 1×10⁶ mPa·s (25° C.) or less after 3 minutes from application;

(10)

(a) the first metal foil or the second metal foil protrudes beyond the other at the both ends in the width of the roll laminate in a plan view of the first and the second metal foil,

(b) one of the first metal foil and the second metal foil protrudes beyond the other metal foil at one end of the roll laminate in the width direction, and the other metal foil protrudes beyond the other at the other end of the roll laminate in the width direction in a plan view of the first and the second metal foil, or

(c) one of the first metal foil and the second metal foil protrudes beyond the other metal foil at one end of the roll laminate in the width direction, and the first and the second metal foil have aligned end portions at the other end of the roll laminate in the width direction in a plan view of the first and the second metal foil;

(11) the first metal foil is a carrier for a carrier-attached metal foil that includes a carrier, an interlayer, and an ultrathin metal layer, in this order, and the second metal foil is the ultrathin metal layer; and

(12) the first metal foil and the second metal foil each comprise a carrier-attached metal foil that includes a carrier, an interlayer, and an ultrathin metal layer, in this order.

Yet another aspect of the present invention is a method for producing a laminate, the method comprising taking the first and the second metal foil from the roll laminate of the present invention, or from a roll laminate produced by the method of the present invention to produce a laminate that includes the first and the second metal foil.

Still another aspect of the present invention is a method for producing a build-up substrate,

the method comprising:

forming one or more build-up wiring layers on at least one surface of a laminate produced by a method for producing a laminate that includes a first and a second metal foil, or on at least one surface of a laminate produced by the method of the present invention by taking the first and the second metal foil from (i) a roll laminate comprising a long first metal foil and a long second metal foil that are bonded to each other via an adhesive layer, and are wound around a support, wherein the adhesive layer has a thickness of 1 μm or more in at least a part of the layer, and is provided along the longitudinal direction of the first and the second metal foil in at least both edge portions in the width of an overlapping region of the first and the second metal foil viewed in plan, or (ii) a roll laminate produced by the method of the present invention.

In another embodiment of the build-up substrate producing method of the present invention, the build-up wiring layers are formed by using at least one of a subtractive method, a full-additive method, and a semi-additive method.

Yet another aspect of the present invention is a method for producing a build-up substrate,

the method comprising:

laminating at least once a resin, a one-sided or double-sided wiring board, a one-sided or double-sided metal clad laminate, a laminate A, a laminate produced by the method of the present invention, a resin substrate-attached metal layer, a carrier-attached metal layer, a wire, a circuit, or a metal layer on at least one surface of a laminate A produced by a method for producing a laminate A that includes a first and a second metal foil, or on at least one surface of a laminate produced by the method of the present invention by taking the first and the second metal foil from (i) a roll laminate comprising a long first metal foil and along second metal foil that are bonded to each other via an adhesive layer, and are wound around a support, wherein the adhesive layer has a thickness of 1 μm or more in at least a part of the layer, and is provided along the longitudinal direction of the first and the second metal foil in at least both edge portions in the width of an overlapping region of the first and the second metal foil viewed in plan, or (ii) a roll laminate produced by the method of the present invention.

In still another aspect of the present invention, the build-up substrate producing method of the present invention further comprises:

boring the resin, the one-sided or double-sided wiring board, the one-sided or double-sided metal clad laminate, the laminate A, a laminate produced by the method of the present invention, the resin substrate-attached metal layer, the carrier-attached metal layer, the wire, the circuit, or the metal layer; and

subjecting a side surface and a bottom surface of the bore to conductive plating.

In yet another aspect of the present invention, the build-up substrate producing method of the present invention further comprises:

forming a wire at least once on at least one of a metal layer constituting the one-sided or double-sided wiring board, a metal layer constituting the one-sided or double-sided metal clad laminate, a metal foil constituting the laminate A, a metal foil constituting a laminate produced by the method of the present invention, a metal layer constituting the carrier-attached metal layer, a metal layer constituting the resin substrate-attached metal layer, and the metal layer.

In an embodiment of the build-up substrate producing method of the present invention, the method further comprises:

laminating, on a wire formed surface, a laminate produced by a method for producing a laminate that includes the first and the second metal foil, or a laminate produced by the method of the present invention by taking the first and the second metal foil from (i) a roll laminate comprising a long first metal foil and a long second metal foil that are bonded to each other via an adhesive layer, and are wound around a support, wherein the adhesive layer has a thickness of 1 μm or more in at least a part of the layer, and is provided along the longitudinal direction of the first and the second metal foil in at least both edge portions in the width of an overlapping region of the first and the second metal foil viewed in plan, or (ii) a roll laminate produced by the roll laminate producing method of the present invention.

In still another aspect of the present invention, the build-up substrate producing method of the present invention further comprises cutting the laminate A or a laminate produced by the method of the present invention at at least one laminated surface of the metal foils viewed in plan.

In yet another aspect of the present invention, the build-up substrate producing method of the present invention further comprises detaching and separating the metal foils of the cut laminate from each other.

In still another aspect of the present invention, the build-up substrate producing method of the present invention further comprises removing the detached and separated metal foil either in part or as a whole by etching.

Yet another aspect of the present invention is a method for producing a printed wiring board, wherein the method uses a laminate produced by a method for producing a laminate that includes the first and the second metal foil, a laminate produced by the method of the present invention, or a build-up substrate produced by the method of the present invention by taking the first and the second metal foil from the roll laminate of the present invention, or from a roll laminate produced by the method of the present invention.

Still another aspect of the present invention is a method for producing an electronic device using a printed wiring board produced by the method of the present invention.

### Advantageous Effects of Invention

The present invention can provide a roll laminate that can desirably reduce scrapes on a metal foil surface even when a long metal foil is wound into a roll, and that can improve the productivity in use of the unwound roll metal foil.

### BRIEF DESCRIPTION OF DRAWINGS

FIG. 1 is a cross sectional view showing a structure of a roll laminate in an embodiment of the present invention.

FIG. 2 is a schematic view describing a roll laminate producing method of the present invention.

FIGS. 3A and 3B are cross sectional views of laminates of a first and a second metal foil obtained after unwinding and cutting a roll laminate according to another embodiment of the present invention.

FIGS. 4A-4F are cross sectional views and plan views of laminates of a first and a second metal foil obtained after unwinding and cutting a roll laminate according to another embodiment of the present invention.

FIGS. 5A and 5B are schematic views showing cross sections of the first and the second metal foil, explaining how the thickness of the adhesive layer is measured in the present invention.

FIG. 6 is a schematic view showing an outline of a cross section of the roll laminate.

### DESCRIPTION OF EMBODIMENTS

Roll laminate

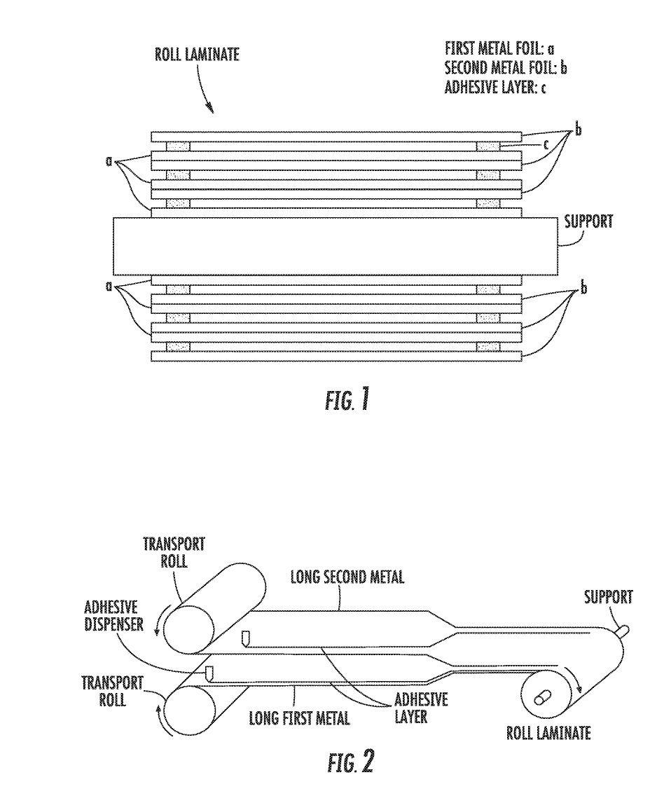

FIG. 1 is a cross sectional view showing a structure of a roll laminate of the present invention. FIG. 2 shows a schematic view describing a method for producing the roll laminate of the present invention. The roll laminate of the present invention includes a long first metal foil and a long second metal foil that are bonded to each other via an adhesive layer, and are wound around a support. In the present invention, the second metal foil of the roll laminate may be read as a first metal foil, and the first metal foil of the roll laminate may be read as a second metal foil.

The support may have a columnar or a tubular form. For example, the support may have a form of a column or a cylinder, and may be made of a material such as metal, resin, and paper. For cost and ease of handling, the support may be, for example, a spool (paper core).

In an embodiment of the roll laminate producing method of the present invention, as shown in FIG. 2, an adhesive layer may be provided along the longitudinal direction (MD: machine direction) of the long first metal foil in both edge portions in the width of the first metal foil, using an adhesive dispenser, and the long second metal foil is bonded to the surface on the adhesive layer side of the first metal foil provided with the adhesive layer. After being bonded to each other via the adhesive layer, the long first metal foil and the long second metal foil can be wound around the support to obtain the roll laminate. As illustrated in the cross sectional block diagram of FIG. 1, the roll laminate produced in this manner is a long laminate of a two-layer structure of the long first and second metal foils that are bonded to each other via an adhesive layer, and the laminate is wound around the support. The long laminate of the two-layer structure is wound multiple times to constitute the roll laminate. The adhesive layer may be provided in portions other than both edge portions in the width of the first metal foil.

The adhesive layer may be provided either continuously or discontinuously along the longitudinal direction of the first and the second metal foil. As shown in FIG. 2, the adhesive layer is provided along the longitudinal direction of the first and the second metal foil. As shown in FIG. 3A, an additional adhesive layer may be provided between the adhesive layers provided at the both edge portions in the width of the first and second metal foils. As shown in FIG. 3B, a plurality of additional adhesive layers maybe provided between the adhesive layers provided at the both edge portions in the width of the first and second metal foils. The adhesive layers provided between the first and second metal foils may have the same or different widths. For example, the lower limit of the adhesive layer width is preferably 0.5 mm or more, preferably 1 mm or more, preferably 1.5 mm or more, preferably 2 mm or more, preferably 2.5 mm or more, preferably 3 mm or more, though it is not particularly limited. When the adhesive layer has a width of 0.5 mm or more, the first metal foil and the second metal foil can be sufficiently bonded to each other, and accidental detachment of the first metal foil and the second metal foil becomes less likely to occur in production of a printed wiring board. The upper limit of the adhesive layer width is, for example, preferably 100 mm or less, preferably 95 mm or less, preferably 90 mm or less, preferably 50 mm or less, preferably 30 mm or less, preferably 20 mm or less, preferably 10 mm or less, though it is not particularly limited. Preferably, the width of the adhesive layer is 100 mm or less because it requires less adhesive, and allows wider areas of the first metal foil and the second metal foil to be used in applications such as in a printed wiring board.

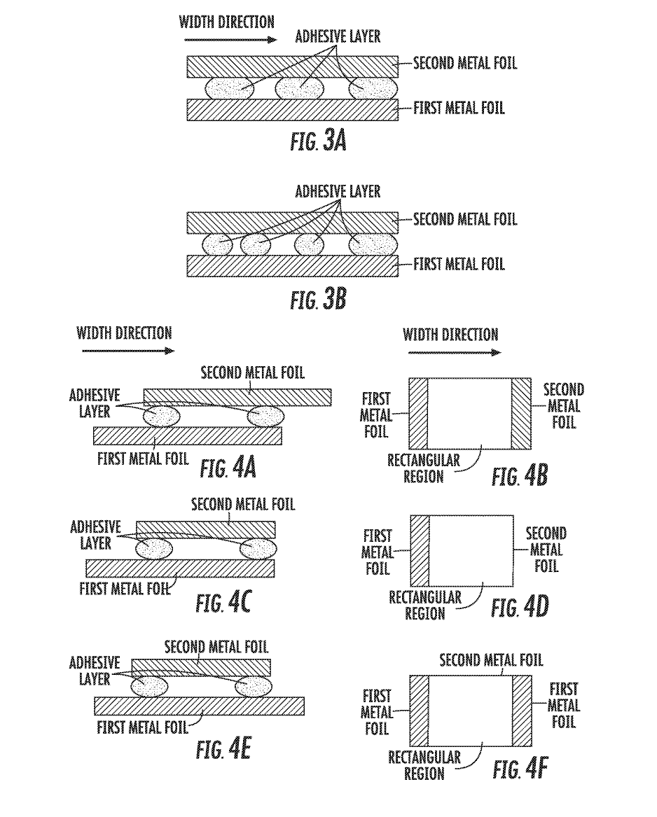

The adhesive layer has a thickness of 1 μm or more in at least a part of the layer, and is provided along the longitudinal direction of the first and the second metal foil in at least both edge portions in the width of an overlapping region of the first and the second metal foil of the roll laminate viewed in plan. As used herein, “both edge portions” refers to regions within 20% from each end of a planar overlapping region of the first and the second metal foil in the width direction of the first and the second metal foil. Examples of “the planar overlapping region of the first and the second metal foil” are shown in the schematic plan views of FIGS. 4B, 4D and 4F.

The width of the planar overlapping region of the first and the second metal foil of the roll laminate is not particularly limited. It is, however, preferable that the width of the planar overlapping region be at least 50%, at least 60%, at least 70%, at least 80%, at least 90%, or at least 95% of the same width of the first and the second metal foil, or of the width of the narrower of the first and the second metal foil. Preferably, the width of the overlapping region of the first and the second metal foil is at least 50% of the same width of the first and the second metal foil, or at least 50% of the width of the narrower of the first and the second metal foil because it further prevents scrapes on the first and the second metal foil.

As described above, the adhesive layer has a thickness of 1 μm or more in at least a part of the layer, and is provided along the longitudinal direction of the first and the second metal foil in at least both edge portions in the width of an overlapping region of the first and the second metal foil viewed in plan. In this way, the first and the second metal foil are less likely to rub against each other when producing the roll laminate, or when using the roll laminate to produce a laminate or a printed wiring board. The metal foils are accordingly less likely to have scrapes on the laminated surface. The planar overlapping region of the first and the second metal foil may be rectangular in shape. Preferably, the adhesive layer has a thickness of 1 μm or more in at least one of an outer portion, a middle portion, and an inner portion of the roll laminate. Preferably, the adhesive layer has a thickness of 1 μm or more in at least two, more preferably all of an outer portion, a middle portion, and an inner portion of the roll laminate. Preferably, the adhesive layer has a thickness of 1 μm or more over the entire length. When the adhesive layer has a thickness of 1 μm or more in all of an outer portion, a middle portion, and an inner portion, the adhesive layer can be regarded as having a thickness of 1 μm or more over the entire length of the roll laminate. Because removal of interleaving paper or the like is not needed when taking the metal foils from the roll laminate for processing, the first and the second metal foil can be processed in the laminated state. This improves productivity. Further, the tension applied to the metal foil surfaces becomes considerably small in regions where the adhesive layers are not provided. Specifically, when the metal foils are electrolytic copper foils, the roll laminate can be prevented from a loss of S (shiny) surface smoothness due to transfer of the coarse shape of the M (matte) surface to the S surface, or a loss of anchoring effect due to nodules exfoliating from the M surface upon contact between the M surface and the S surface of the copper foils. The roll laminate also can be prevented from scrapes (abrasions) occurring when the copper foils rub or slide (telescoping) against each other in the roll during transport such as by a truck. It is also possible to prevent wrinkles on the metal foils caused by the difference between inner and outer perimeters. The roll laminate can be used as a copper foil laminate for printed circuit boards. With the foregoing configuration, the laminate can have improved strength, and deformation of the metal foils can be prevented while improving ease of handling. It is also possible to desirably reduce adhesion of contaminants such as a resin powder to metal foil surfaces. These contribute to overall improvement of the productivity and the yield of a printed board. When the thickness of the adhesive layer is less than 1 μm throughout the roll laminate, the first metal foil and the second metal foil may rub against each other, and cause scrapes.

The first metal foil and the second metal foil constituting the roll laminate may have forms other than having the same size in width direction as shown in FIG. 1 to FIGS. 3A and 3B. FIGS. 4A-4F illustrate specific examples of such forms. FIG. 4A shows a schematic cross sectional view of the first and the second metal foil constituting the roll laminate, and FIG. 4B shows a plan view of the first and the second metal foil. In FIGS. 4A and 4B, one of the first metal foil and the second metal foil protrudes beyond the other metal foil at one end of the roll laminate, and the other metal foil protrudes beyond the other at the other end of the roll laminate in the width direction in a plan view of the first and the second metal foil.

FIG. 4C shows a cross sectional schematic view of the first and the second metal foil constituting the roll laminate, and FIG. 4D shows a plan view of the first and the second metal foil. In FIGS. 4C and 4D, one of the first metal foil and the second metal foil protrudes beyond the other metal foil at one end of the roll laminate in the width direction, and both of the first and the second metal foil have aligned end portions at the other end of the roll laminate in the width direction in a plan view of the first and the second metal foil.

FIG. 4E shows a cross sectional schematic view of the first and the second metal foil constituting the roll laminate, and FIG. 4F shows a plan view of the first and the second metal foil. In FIGS. 4E and 4F, one of the first metal foil and the second metal foil protrudes beyond the other metal foil at the both ends of the roll laminate in the width direction in a plan view of the first and the second metal foil.

With regard to the size in the width direction of the first and the second metal foil constituting the roll laminate, the first metal foil and the second metal foil can be easily distinguished from each other by making at least one of the metal foils protrude beyond the other. The protrusion also makes it easier to peel the first metal foil or the second metal foil from the other because it allows the protruding metal foil to be held and peeled when the first metal foil and the second metal foil need to be separated. This makes the procedure more efficient. The protrusion also allows for printing or writing of a lot number or other information, and makes it easier to distinguish among different roll laminates, or among laminates obtained after unwinding and cutting the roll laminate. This makes the procedure more efficient. The protrusion of one of the metal foils also serves to protect the corners of the other metal foil, and prevents bending or deformation of the metal foil during transport or handling.

The minimum length by which the first metal foil or the second metal foil protrudes from the other metal foil is not particularly limited. For example, the protrusion length is preferably 0.5% or more, preferably 1% or more, preferably 2% or more, preferably 5% or more of the same width of the first metal foil and the second metal foil, or of the width of the wider of the first metal foil and the second metal foil. The foregoing effects become more pronounced when the protrusion length is 0.5% or more of the same width of the first metal foil and the second metal foil, or of the width of the wider of the first metal foil and the second metal foil.

The maximum length by which the first metal foil or the second metal foil protrudes from the other metal foil is not particularly limited. For example, the protrusion length is preferably 40% or less, preferably 35% or less, preferably 30% or less, preferably 25% or less, preferably 20% or less, preferably 15% or less of the same width of the first metal foil and the second metal foil, or of the width of the wider of the first metal foil and the second metal foil. The first metal foil and the second metal foil become less likely to be scraped when the protrusion length is 40% or less of the same width of the first metal foil and the second metal foil, or of the width of the wider of the first metal foil and the second metal foil.

The thickness of the adhesive layer is preferably 2 μm or more, more preferably 3 μm or more, further preferably 5 μm or more. The upper limit of the adhesive layer thickness is preferably 500 μm or less, preferably 400 μm or less, preferably 300 μm or less, preferably 200 μm or less, preferably 100 μm or less, preferably 50 μm or less, though it is not particularly limited. Smaller thicknesses are preferred because thinner adhesive layers use less amounts of adhesive, and can reduce the manufacturing cost.

In the present invention, the thickness of the adhesive layer is measured as follows.

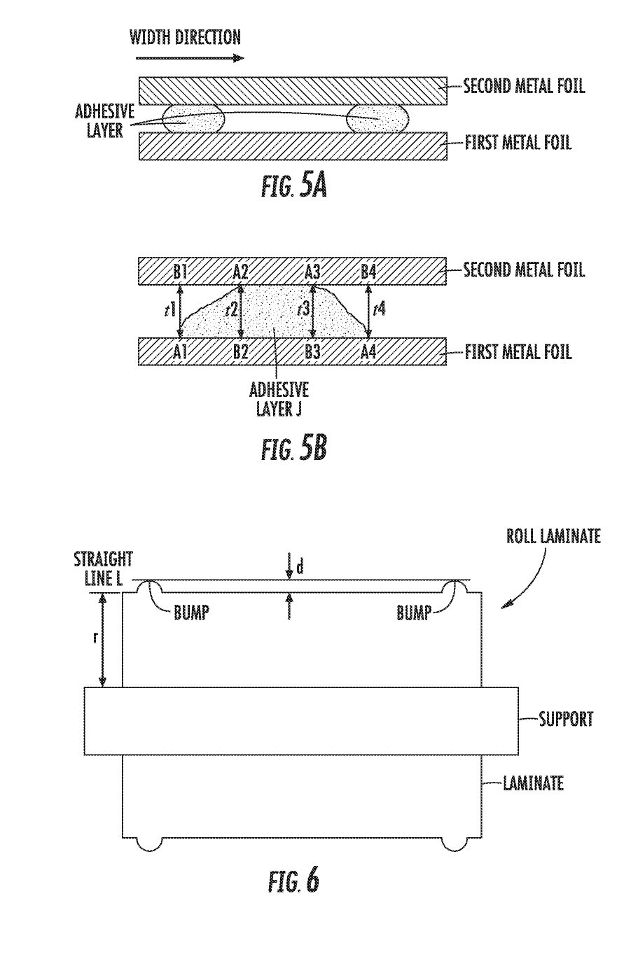

FIG. 5A shows a cross sectional view of the first and the second metal foil after unwinding and cutting the roll laminate into a laminate of the first and the second metal foil. In the cross sectional view, the thickness of the adhesive layer (adhesive layer J as the example shown in FIG. 5B) is measured as the mean value of the distance of a straight line extending along the thickness of the metal foil and connecting point A, where an edge of the adhesive layer J meets one of the metal foils, and point B, where the straight line crosses the other metal foil, as shown in FIG. 5B. The edges of the adhesive layer J on the metal foils are at points A1 to A4. B1 to B4 are points where the straight lines extending from points A1 to A4 along the thickness direction of the metal foil reach the other metal foil, respectively. When the distances from A1 to B1, A2 to B2, A3 to B3, and A4 to B4 are t1, t2, t3, and t4, respectively, the thickness of the adhesive layer J is given as the arithmetic mean value of tl to t4.

Thickness t of adhesive layer J=(t1+t2+t3+t4)/4

When more than one adhesive layer is present in a cross section of the laminate of the first and the second metal foil, the adhesive layer thickness is given as the arithmetic mean value of the thicknesses of the adhesive layers calculated by the method described above. As a specific example, when two adhesive layers are present in a cross section of the laminate of the first and the second metal foil, the adhesive layer thickness is the arithmetic mean value of the thicknesses of the two adhesive layers.

In the present invention, the width of the adhesive layer is measured as follows.

In FIG. 5B, the distance from A1 to A4 is w1. The distance from A2 to A3 is w2. The width of the adhesive layer J is the arithmetic mean value of width w1 and width w2.

Width w of adhesive layer J=(w1+w2)/2

When more than one adhesive layer is present in a cross section of the laminate of the first and the second metal foil, the adhesive layer width is given as the arithmetic mean value of the widths of the adhesive layers calculated by the method described above. As a specific example, when two adhesive layers are present in a cross section of the laminate of the first and the second metal foil, the adhesive layer width is the arithmetic mean value of the widths of the two adhesive layers.

When the metal foils to be bonded to each other are cut sheets, the metal foils need to be pressed down with a roller to remove air between the cut sheets and within the laminate, and the adhesive is cured to bond the metal foils. In contrast, when the first metal foil and the second metal foil are bonded to each other via the adhesive layer to produce the roll laminate as in the present invention, air is discharged while rolling and winding the metal foils, and no extra step is needed to remove air.

The first metal foil and the second metal foil may be taken from the roll laminate, and one of the metal foils may be bonded to a prepreg sheet such as a glass fiber-reinforced epoxy resin to produce a prepreg sheet-attached laminate, and use it for lamination to a printed circuit board. Such a configuration improves the laminate strength, and prevents deformation of the metal foil. It also becomes easier to handle the metal foil, and adhesion of contaminants such as a resin powder to the metal foil surface can be desirably reduced.

In the roll laminate of the present invention, the laminate wound around the support is a two-layer which has laminated structure of the first and the second metal foil with the adhesive layer provided in both edge portions in the width of the first and the second metal foils. In this case, as schematically outlined view in the cross section shown in FIG. 6, bumps may occur on the outermost surface of the roll laminate in the thickness direction of the first and the second metal foil in positions corresponding to the adhesive layers provided in both edge portions in the width of the first and the second metal foil. Here, when a straight line drawn to connect the apices of the bumps is L, it is preferable that the maximum depth (d) of the gap created between the straight line L and the outermost surface of the roll laminate, and the roll thickness (r) of the roll laminate satisfy the formula 0≦d≦0.1×r.

The gap will be sufficiently small when the maximum depth (d) of the gap created between the straight line L and the outermost surface of the roll laminate is within 10% of the roll thickness (r) of the roll laminate, and contact between the first and the second metal foil due to bending of the first and the second metal foil in the roll laminate can be desirably reduced.

More preferably, the maximum depth (d) of the gap created between the straight line L and the outermost surface of the roll laminate, and the roll thickness (r) of the roll laminate satisfy the formula 0≦d≦0.05×r, or, typically, 500 μm ≦d≦0.1×r.

The roll thickness r is not particularly limited, but is typically 5 mm or more, 10 mm or more, 50 mm or more, 70 mm or more, or 100 mm or more, and is typically 1,500 mm or less, 1,400 mm or less, 1,300 mm or less, 1,000 mm or less, or 900 mm or less.

Preferably, the adhesive constituting the adhesive layer has a viscosity of 3×10⁶ mPa·s (25° C.) or less after 3 minutes from application. When the viscosity of the adhesive layer is excessively high, the first metal foil and the second metal foil become overly fixed, and wrinkles or cracks may occur as such excessively high viscosity makes it difficult to accommodate an externally applied load. When the viscosity of the adhesive constituting the adhesive layer is 3×10⁶ mPa·s (25° C.) or less after 3 minutes from application, an externally applied load can be accommodated even though the first and the second metal foil are bonded, and wrinkles and cracks can be reduced. Preferably, the viscosity of the adhesive constituting the adhesive layer is 1×10⁶ mPa·s (25° C.) or less after 3 minutes from application.

The adhesive constituting the adhesive layer may be, for example, at least one of an epoxy-based adhesive, an acrylic-based adhesive, a methacrylate-based adhesive, silicon rubber-based adhesive, a ceramic-based adhesive, and a rubber-based adhesive.

The long first metal foil, and the long second metal foil are not particularly limited, as long as these are metal foils. For example, the first and the second metal foil may be any of a copper foil, an electrolytic copper foil, a rolled copper foil, a copper alloy foil, a nickel foil, a nickel alloy foil, an iron foil, an iron alloy foil, a stainless steel foil, an aluminum foil, an aluminum alloy foil, a zinc foil, and a zinc alloy foil.

Preferably, the long first metal foil and the long second metal foil each have a thickness of 5 to 70 μm, respectively. With such a configuration, the first and the second metal foil do not bend as much as the thickness, 1 to 50 μm, of the adhesive layer (i.e., the gap between the first metal foil and the second metal foil), and contact between the first and the second metal foil can be desirably reduced.

It is not necessarily required to limit the width of the metal foil used for the roll laminate. However, the metal foil has a width of typically 100 mm or more, 200 mm or more, or 300 mm or more, and a width of typically 3,000 mm or less, 2,500 mm or less, 2,000 mm or less, 1,800 mm or less, 1,600 mm or less, or 1,500 mm or less. As used herein, “metal foil” may include the first metal foil, and the second metal foil.

The length of the metal foil used for the roll laminate is not particularly limited either. However, the metal foil has a length of typically 10 m or more, 20 m or more, or 30 m or more, and a length of typically 50,000 m or less, 40,000 m or less, 30,000 m or less, 20,000 m or less, or 18,000 m or less.

The roll laminate of the present invention may be a roll laminate that does not fall into the following categories (A) to (C) of the roll laminate.

(A) A roll laminate consisting of a structure in which:

only a first insulating layer and a first copper foil layer are provided in such order that the roll laminate has the first insulating layer on the surface of the first metal foil opposite the surface that is in contact with the second metal foil, and the first copper foil layer on the surface of the first insulating layer opposite the first metal foil, and

only a second insulating layer and a second copper foil layer are provided in such order that the roll laminate has the second insulating layer on the surface of the second metal foil opposite the surface that is in contact with the first metal foil, and the second copper foil layer on the surface of the second insulating layer opposite the surface that is in contact with the second metal foil.

(B) A roll laminate consisting of a structure in which:

only a first insulating layer, a first copper foil layer, and a via hole are provided, wherein the first insulating layer is provided on the surface of the first metal foil opposite the surface that is in contact with the second metal foil, the first copper foil layer is provided on the surface of the first insulating layer opposite the surface that is in contact with the first metal foil, and the via hole is provided through the first insulating layer and the first copper foil layer, and

only a second insulating layer, a second copper foil layer, and a via hole are provided, wherein the second insulating layer is provided on the surface of the second metal foil opposite the surface that is in contact with the first metal foil, the second copper foil layer is provided on the surface of the second insulating layer opposite the surface that is in contact with the second metal foil, and the via hole is provided through the second insulating layer and the second copper foil layer.

(C) A roll laminate consisting of a structure in which:

only a first insulating layer, a first copper foil layer, a first metal layer, and a first via hole are provided, wherein the first insulating layer is provided on the surface of the first metal foil opposite the surface that is in contact with the second metal foil, the first copper foil layer is provided on the surface of the first insulating layer opposite the surface that is in contact with the first metal foil, the first via hole is provided through the first insulating layer and the first copper foil layer, and the first metal layer is provided on the surface of the first copper foil layer opposite the surface that is in contact with the first insulating layer, and in the first via hole, and

only a second insulating layer, a second copper foil layer, a second metal layer, and a second via hole are provided, wherein the second insulating layer is provided on the surface of the second metal foil opposite the surface that is in contact with the first metal foil, the second copper foil layer is provided on the surface of the second insulating layer opposite the surface that is in contact with the second metal foil, the second via hole is provided through the second insulating layer and the second copper foil layer, and the second metal layer is provided on the surface of the second copper foil layer opposite the surface that is in contact with the second insulating layer, and in the second via hole.

### Carrier-Attached Metal Foil

The roll laminate of the present invention may be a roll laminate in which the first metal foil and the second metal foil are carrier-attached metal foils each having a carrier, an interlayer, and an ultrathin metal layer, in this order. In this case, the roll laminate may be produced by bonding the carrier-side surface of the first metal foil (first carrier-attached metal foil) to the carrier-side surface of the second metal foil (second carrier-attached metal foil) via the adhesive layer. Here, a coreless substrate can be produced by using a laminate in which the first and the second carrier-attached metal foil are bonded to each other on the carrier side via the adhesive layer. The laminate may be one obtained by cutting the laminate having the first metal foil and the second metal foil after taking them from the roll laminate. Preferably, the ultrathin metal layer may be an ultrathin copper layer. As used herein, “carrier-attached metal foil” may include carrier-attached copper foil. In the specification, the carrier-attached metal foil may be read as carrier-attached copper foil.

The roll laminate also can be produced by bonding the carrier-side surface of the first metal foil (first carrier-attached metal foil) or the second metal foil (second carrier-attached metal foil) to the ultrathin metal layer-side surface of the other metal foil via the adhesive layer.

The roll laminate also may be one produced by bonding the ultrathin metal layer-side surface of the first metal foil (first carrier-attached metal foil) or the second metal foil (second carrier-attached metal foil) to the ultrathin metal layer-side surface of the other metal foil via the adhesive layer. The first and the second carrier-attached metal foil may be known carrier-attached metal foils.

The manufacturing process of the roll metal foil of the carrier-attached metal foil for printed circuit boards is described below. The carrier-attached metal foil is typically configured to include the ultrathin metal layer formed by being bonded to the whole surface of the carrier via a release layer so that the ultrathin metal layer can be easily peeled off. Specifically, when the ultrathin metal layer is configured as an electrolytic metal foil, the matte surface is formed on the side that faces the carrier. During manufacture, a carrier-attached metal foil with the metal layer bonded to the whole surface of the carrier is wound around, for example, a paper core with the matte surface of the ultrathin metal layer contacting the carrier. Here, the matte surface of the ultrathin metal layer often experiences damage caused by contact with the carrier. For example, because the carrier and the ultrathin metal layer rub against each other, nodules (particles generated from roughening) often exfoliate from the roughened layer formed on the matte surface of the ultrathin metal layer. Abrasions (scratches) due to vibration may also occur during transport of the roll metal foil (copper foil). In contrast, the carrier and the ultrathin metal layer are less likely to be damaged by the configuration of the present invention described above because the carrier-attached metal foils are wound around the support after bonding the carriers via the adhesive layer, or after bonding the carrier of either carrier-attached metal foil to the ultrathin metal layer of the other. A laminate with the two-layer bonded structure of the carrier and the ultrathin metal layer typically experiences a tension of 100 to 1,000 N/m when being wound around a support. Because the load of the tension concentrates on the adhesive layer, the foregoing configuration desirably reduces abrasions (scratches) between the carrier and the ultrathin metal layer, and exfoliation of nodules from the matte surface.

Removal of interleaving paper or the like is also not necessary for processing of the metal foil (carrier-attached metal foil) taken from the roll laminate, and the first and the second metal foil (the first and the second carrier-attached metal foil) can be processed directly in the laminated state. This improves productivity. Further, because the first and the second metal foil being would into a roll are less likely to experience tension in portions where the adhesive layer is not provided, the matte surfaces of the first and the second metal foil (matte surfaces of the ultrathin metal layers of the first and the second carrier-attached metal foil) are less likely to rub against and contact each other in these portions, making it possible to desirably reduce the foreign object metal powder that occurs at the laminated surface from the matte surface. It is also possible to improve the ease of handling when rolling out the first and the second metal foil for use (when taking the metal foils from the roll laminate for use).

As used herein, “carrier-attached metal foil” may include a carrier-attached copper foil. As used herein, “ultrathin metal layer” may include an ultrathin copper layer. As used herein, “electrolytic metal foil” may include an electrolytic copper foil. As used herein, “roll metal foil” may include a roll copper foil.

The carrier-attached metal foils obtained from the roll laminate may be used to produce a printed wiring board, as follows. For example, the ultrathin metal layer surface or the carrier surface is attached to an insulating substrate such as a paper base phenolic resin, a paper base epoxy resin, a synthetic fiber fabric base epoxy resin, a glass fabric-paper composite base epoxy resin, a glass fabric-glass nonwoven fabric composite base epoxy resin, a glass fabric base epoxy resin, a polyester film, and a polyimide film. After thermocompression, the ultrathin metal layer or the carrier is peeled off, and etched to form the desired conductor pattern to produce a printed wiring board.

As an example of use of the roll laminate, the roll laminate provided to the manufacturing process may be cut into a sheet of the desired length, and the resulting laminate of the first and the second metal foil (hereinafter, also referred to as “sheet metal foil laminate”) may be stacked to make a repeat of a configuration constructed from the sheet metal foil laminate, a prepreg, the sheet metal foil laminate, and an SUS middle plate, and followed by hot press. As another example, a metal foil laminate rolled out of the roll laminate may be used to make a configuration constructed from the metal foil laminate, a prepreg, and the metal foil laminate, and laminated with a hot-press roll (roll-to-roll method) to produce, for example, a metal (copper) clad laminate plate.

### Laminate, Build-Up Substrate, Printed Wiring Board, and Electronic Device

The first and the second metal foil may be taken from the roll laminate of the present invention, and cut to produce a laminate having the first and the second metal foil. A coreless build-up substrate can be produced by forming one or more build-up wiring layers on at least one surface of the laminate, or on at least one surface of a laminate having a form in which the first and the second metal foil are contained by being covered with a resin layer and the other metal foil.

The build-up wiring layer may be formed by using one or more of the subtractive method, the full-additive method, and the semi-additive method. A build-up substrate can be produced by laminating a resin, a one-sided or double-sided wiring board, a one-sided or double-sided metal clad laminate, a laminate produced by the method of the present invention, a resin substrate-attached metal layer, a carrier-attached metal layer, a wire, a circuit, or a metal layer at least once on at least one surface of a laminate produced by the method of the present invention. The resin, the one-sided or double-sided wiring board, the one-sided or double-sided metal clad laminate, the laminate, the resin substrate-attached metal layer, the carrier-attached metal layer, the wire, the circuit, or the metal layer may be bored, and the side surface and the bottom surface of the bore may be subjected to conductive plating.

A build-up substrate may be produced by forming a wire at least once on at least one of a metal layer constituting the one-sided or double-sided wiring board, a metal layer constituting the one-sided or double-sided metal clad laminate, a metal foil constituting the laminate, a metal layer constituting the carrier-attached metal layer, a metal layer constituting the resin substrate-attached metal layer, and the metal layer. A laminate produced by the method of the present invention may be further laminated on the wired surface to produce a build-up substrate. A build-up substrate may be produced by cutting the laminate at at least one laminated surface of the metal layers viewed in plan. The metal layers in the cut laminate may be detached and separated from each other to produce a build-up substrate. The detached and separated metal layer may be removed either in part or as a whole by etching to produce a build-up substrate.

A resin layer may be laminated on the both outer surfaces of the laminate of the first and the second metal foil, and a metal foil may be laminated on the resin layer. Here, the resin layer, and the overlying metal foil maybe larger in size than the first and the second metal foil so that the laminate has a form in which the resin layer and the overlying metal foil cover and contain the first and the second metal foil. The first and the second metal foil may be carrier-attached metal foils. A known resin, and/or a known prepreg may be used for the resin layer. The resin layer may be plate-shaped.

The laminate or the build-up substrate obtained by using the method of the present invention may be used to produce a printed wiring board. The printed wiring board becomes a complete printed circuit board upon mounting electronic components. In the present invention, “printed wiring board” encompasses printed wiring boards, printed circuit boards, and printed boards having electronic components mounted thereon.

The printed wiring board may be used to produce an electronic device. The printed circuit board with the mounted electronic components may be used to produce an electronic device. The printed board with the mounted electronic components may be used to produce an electronic device.

### EXAMPLES

The present invention is described below in greater detail by way of Examples. It is to be noted that the present invention is in no way limited by the following Examples.

As a rule, an adhesive cures after application, and its viscosity constantly varies with time. To take this into consideration, the viscosity of the adhesive used was measured in advance at 25° C. after 3 minutes from application, using a rotary viscometer (B-type viscometer, a Brookfield rotary viscometer HA DV3T available from Brookfield). The viscosity of the adhesives used in the Examples below was adjusted by adjusting the degree of polymerization of the polymer material contained in the adhesive.

### Example 1

### 1. Production of Roll Laminate

The long first and the second metal foil were transported with the transport rolls of the manufacturing apparatus prepared as shown in FIG. 2. An electrolytic copper foil measuring 12 μm in thickness and 500 mm in width was used as the first metal foil. For the second metal foil, an 18 μm-thick, 500 mm-wide rolled copper foil was used.

Thereafter, an acrylic adhesive layer having a viscosity of 3×10⁶ mPa·s (25° C.) or less after 3 minutes from application was continuously applied along the longitudinal direction of the first metal foil at both edge portions of the S surface in the width of the long first metal foil.

The S surface of the long first metal foil was then bonded to the S surface of the long second metal foil via the adhesive layer to form a laminate of a two-layer structure, and the laminate was wound around a support spool to produce the roll laminate as shown in FIGS. 1 and 6.

### 2. Evaluation of Roll Laminate

The adhesive layer had thicknesses of 8.5 μm, 10 μm, and 11.3 μm at an outer portion, a middle portion, and an inner portion, respectively, of the roll laminate. The adhesive layer had widths of 0.8-mm, 0.6-mm, and 0.5-mm at the outer portion, the middle portion, and the inner portion, respectively, of the roll laminate. The thickness and the width of the adhesive layer were measured in the manner described below (the original roll thickness of the roll laminate is r1 [mm]).

### Sampling

Outer portion: the first surface layer of the roll laminate was peeled away, and the second layer of the laminate was cut into a sheet form.

Middle portion: the roll laminate was unwound until the roll thickness became r1×(½±0.05), and the laminate was cut into a sheet form.

Inner portion: the roll laminate was unwound until the roll thickness became r1×0.1 to r1×0.05, and the laminate was cut into a sheet form.

The outer, middle, and inner sheet-like shaped laminates were then measured the thickness and the width of the adhesive layer at two locations on the cut cross section of each laminate in the manner described above, and the arithmetic mean values of the thicknesses and the widths of the adhesive layer were determined for these two locations.

The first and the second metal foil did not have wrinkles or cracks. The first and the second metal foil did not have scrapes on the adhesive layer-side surfaces upon inspection of the first and the second metal foil taken from the roll laminate, and detached from each other.

On the outermost surface of the roll laminate in the thickness direction of the first and the second metal foil, a straight edge (Matsui Measure MFG, Co., Ltd., flatness ruler, length 600 mm, single blade/no indentation) was placed across the apices of bumps corresponding in position to the adhesive layers formed at both edge portions in the width of the first and the second metal foil. The maximum depth (d) of the gap created between the straight edge and the outermost surface of the roll laminate was 50 μm, and the roll thickness (r) of the roll laminate was 500 mm, satisfying the formula 0≦d≦0.1×r. Instead of the straight edge, a plate or a ruler made of a rigid, undeformable material, for example, metal, and organic material may be used for the measurement. A feeler gauge may be used for the measurement of the maximum depth d. Maximum depth d was measured at three circumferential locations of the roll laminate, and the arithmetic mean value of the three measured values of d was determined as the maximum depth d of the roll laminate.

### Example 2

### 1. Production of Roll Laminate

The long first and the second metal foil were transported with the transport rolls of the manufacturing apparatus prepared as shown in FIG. 2. A carrier-attached copper foil (ultrathin copper layer thickness=5 μm, carrier thickness=18 μm, width=540 mm) was used as the first metal foil. A carrier-attached copper foil (ultrathin copper layer thickness=5 μm, carrier thickness=18 μm, width=540 mm) was used as the second metal foil.

A silicon rubber-based adhesive layer having a viscosity of 3×10⁶ mPa·s (25° C.) or less after 3 minutes from application was continuously applied along the longitudinal direction of the first metal foil at both edge portions of the carrier surface in the width of the long first metal foil (the coated portion was 1 cm in length, and the uncoated portion was 3 cm in length).

The long first metal foil, and the long second metal foil were then bonded to each other on the carrier surfaces via the adhesive layer to form a laminate of a two-layer structure, and the laminate was wound around a support spool to produce the roll laminate as shown in FIGS. 1 and 6.

### 2. Evaluation of Roll Laminate

The adhesive layer had thicknesses of 6.8 μm, 5.0 μm, and 5.2 μm at an outer portion, a middle portion, and an inner portion, respectively, of the roll laminate. The adhesive layer had widths of 1.4-mm, 1.5-mm, and 1.5-mm at the outer portion, the middle portion, and the inner portion, respectively, of the roll laminate. The first and the second metal foil did not have wrinkles or cracks. The first and the second metal foil did not have scrapes on the adhesive layer-side surfaces and the ultrathin copper layer surfaces upon inspection of the first and the second metal foil taken from the roll laminate, and detached from each other.

On the outermost surface of the roll laminate in the thickness direction of the first and the second metal foil, a straight line was drawn across the apices of bumps corresponding in position to the adhesive layers formed at both edge portions in the width of the first and the second metal foil. The maximum depth (d) of the gap created between the straight edge and the outermost surface of the roll laminate was 30 μm, and the roll thickness (r) of the roll laminate was 500 mm, satisfying the formula 0≦d≦0.1×r.

### Example 3

### 1. Production of Roll Laminate

The long first and the second metal foil were transported with the transport rolls of the manufacturing apparatus prepared as shown in FIG. 2. A carrier-attached copper foil (ultrathin copper layer thickness=5μm, carrier thickness=18 μm, width=500 mm) was used as the first metal foil. An aluminum foil (thickness=40 μm, width=510 mm) was used as the second metal foil.

A methacrylate-based adhesive layer having a viscosity of 3×10⁶ mPa·s (25° C.) or less after 3 minutes from application was continuously applied along the longitudinal direction of the first metal foil at both edge portions of the carrier surface in the width of the long first metal foil.

The long first metal foil, and the long second metal foil were then bonded to each other on the carrier surfaces via the adhesive layer to form a laminate of a two-layer structure, and the laminate was wound around a support spool to produce the roll laminate as shown in FIGS. 1 and 6. The laminate of a two-layer structure had a configuration in which the aluminum foil (width=510 mm), or the second metal foil, protruded beyond the carrier-attached copper foil (width=500 mm), or the first metal foil, by 5 mm at each end in the width direction.

### 2. Evaluation of Roll Laminate

The adhesive layer had thicknesses of 2.1 μm, 3.0 μm, and 4.0 μm at an outer portion, a middle portion, and an inner portion, respectively, of the roll laminate. The adhesive layer had widths of 3.5-mm, 3.4-mm, and 3.4-mm at the outer portion, the middle portion, and the inner portion, respectively, of the roll laminate. The first and the second metal foil did not have wrinkles or cracks. The first and the second metal foil did not have scrapes on the adhesive layer-side surfaces and the ultrathin copper layer surfaces upon inspection of the first and the second metal foil taken from the roll laminate, and detached from each other.

On the outermost surface of the roll laminate in the thickness direction of the first and the second metal foil, a straight line was drawn across the apices of bumps corresponding in position to the adhesive layers formed at both edge portions in the width of the first and the second metal foil. The maximum depth (d) of the gap created between the straight edge and the outermost surface of the roll laminate was 10 μm, and the roll thickness (r) of the roll laminate was 500 mm, satisfying the formula 0≦d≦0.1×r.

### Example 4

### 1. Production of Roll Laminate

The long first and the second metal foil were transported with the transport rolls of the manufacturing apparatus prepared as shown in FIG. 2. An electrolytic copper foil measuring 12 μm in thickness and 1,290 mm in width was used as the first metal foil. An electrolytic copper foil measuring 12 μm in thickness and 1,290 mm in width was used as the second metal foil.

An acrylic adhesive layer having a viscosity of 3×10⁶ mPa·s (25° C.) or less after 3 minutes from application was continuously applied along the longitudinal direction of the first metal foil at both edge portions of the S surface in the width of the long first metal foil.

The S surface of the long first metal foil, and the S surface of the long second metal foil were then bonded to each other via the adhesive layer to form a laminate of a two-layer structure, and the laminate was wound around a support spool to produce the roll laminate as shown in FIGS. 1 and 6.

### 2. Evaluation of Roll Laminate

The adhesive layer had thicknesses of 15.9 μm, 10.8 μm, and 13.6 μm at an outer portion, a middle portion, and an inner portion, respectively, of the roll laminate. The adhesive layer had widths of 35.3-mm, 36.1-mm, and 35.8-mm at the outer portion, the middle portion, and the inner portion, respectively, of the roll laminate. The first and the second metal foil did not have wrinkles or cracks. The first and the second metal foil did not have scrapes on the adhesive layer-side surfaces upon inspection of the first and the second metal foil taken from the roll laminate, and detached from each other.

On the outermost surface of the roll laminate in the thickness direction of the first and the second metal foil, a straight line was drawn across the apices of bumps corresponding in position to the adhesive layers formed at both edge portions in the width of the first and the second metal foil. The maximum depth (d) of the gap created between the straight edge and the outermost surface of the roll laminate was 50 μm, and the roll thickness (r) of the roll laminate was 500 mm, satisfying the formula 0≦d≦0.1×r.

This application claims priority from Japanese Patent Application No. 2016-103755, filed on May 24, 2016, the entire disclosure of which is incorporated herein by reference.

1. A roll laminate comprising a long first metal foil and a long second metal foil that are bonded to each other via an adhesive layer, and are wound around a support,
wherein the adhesive layer has a thickness of 1 μm or more in at least a part of the layer, and is provided along the longitudinal direction of the first and the second metal foil in at least both edge portions in the width of an overlapping region of the first and the second metal foil viewed in plan, and
wherein the roll laminate does not fall into the following categories (A) to (C) of roll laminates:
(A) a roll laminate consisting of a structure in which:
only a first insulating layer and a first copper foil layer are provided in such order that the roll laminate has the first insulating layer on the surface of the first metal foil opposite the surface that is in contact with the second metal foil, and the first copper foil layer on the surface of the first insulating layer opposite the first metal foil, and
only a second insulating layer and a second copper foil layer are provided in such order that the roll laminate has the second insulating layer on the surface of the second metal foil opposite the surface that is in contact with the first metal foil, and the second copper foil layer on the surface of the second insulating layer opposite the surface that is in contact with the second metal foil;
(B) a roll laminate consisting of a structure in which:
only a first insulating layer, a first copper foil layer, and a via hole are provided, wherein the first insulating layer is provided on the surface of the first metal foil opposite the surface that is in contact with the second metal foil, the first copper foil layer is provided on the surface of the first insulating layer opposite the surface that is in contact with the first metal foil, and the via hole is provided through the first insulating layer and the first copper foil layer, and
only a second insulating layer, a second copper foil layer, and a via hole are provided, wherein the second insulating layer is provided on the surface of the second metal foil opposite the surface that is in contact with the first metal foil, the second copper foil layer is provided on the surface of the second insulating layer opposite the surface that is in contact with the second metal foil, and the via hole is provided through the second insulating layer and the second copper foil layer; and
(C) a roll laminate consisting of a structure in which:
only a first insulating layer, a first copper foil layer, a first metal layer, and a first via hole are provided, wherein the first insulating layer is provided on the surface of the first metal foil opposite the surface that is in contact with the second metal foil, the first copper foil layer is provided on the surface of the first insulating layer opposite the surface that is in contact with the first metal foil, the first via hole is provided through the first insulating layer and the first copper foil layer, and the first metal layer is provided on the surface of the first copper foil layer opposite the surface that is in contact with the first insulating layer, and in the first via hole, and
only a second insulating layer, a second copper foil layer, a second metal layer, and a second via hole are provided, wherein the second insulating layer is provided on the surface of the second metal foil opposite the surface that is in contact with the first metal foil, the second copper foil layer is provided on the surface of the second insulating layer opposite the surface that is in contact with the second metal foil, the second via hole is provided through the second insulating layer and the second copper foil layer, and the second metal layer is provided on the surface of the second copper foil layer opposite the surface that is in contact with the second insulating layer, and in the second via hole.

2. The roll laminate according to claim 1, wherein the adhesive layer has a thickness of 300 μm or less.

3. The roll laminate according to claim 1, wherein the adhesive layer has a width of 0.5 mm or more.

4. The roll laminate according to claim 1, wherein the adhesive layer has a width of 100 mm or less.

5. The roll laminate according to claim 1, wherein the first metal foil and the second metal foil each have a thickness of 5 to 70 μm.

6. The roll laminate according to claim 1, wherein the adhesive layer is provided either continuously or discontinuously along the longitudinal direction of the first and the second metal foil.

7. A roll laminate comprising a long first metal foil and a long second metal foil that are bonded to each other via an adhesive layer, and are wound around a support,
wherein the adhesive layer has a thickness of 1 μm or more in at least a part of the layer, and is provided along the longitudinal direction of the first and the second metal foil in at least both edge portions in the width of an overlapping region of the first and the second metal foil viewed in plan, and
wherein the roll laminate satisfies the formula 0≦d≦0.1×r, where d is the maximum depth of a gap created between the outermost surface of the roll laminate in the thickness direction of the first and the second metal foil, and a straight line drawn to connect the apices of bumps present on the outermost surface of the roll laminate in positions corresponding to the adhesive layers at both edge portions in the width of the first and the second metal foil, and r is the roll thickness of the roll laminate.

8. The roll laminate according to claim 7, which satisfies at least one of the following (1) to (5):
(1) the adhesive layer has a thickness of 300 μm or less;
(2) the adhesive layer has a width of 0.5 mm or more;
(3) the adhesive layer has a width of 100 mm or less;
(4) the first metal foil and the second metal foil each have a thickness of 5 to 70 μm; and
(5) the adhesive layer is provided either continuously or discontinuously along the longitudinal direction of the first and the second metal foil.

9. The roll laminate according to claim 7, wherein the maximum depth (d) of the gap created between the straight line and the outermost surface of the roll laminate, and the roll thickness (r) of the roll laminate satisfy the formula 0≦d≦0.05×r.

10. The roll laminate according to claim 1, wherein the adhesive constituting the adhesive layer has a viscosity of 3×10⁶ mPa·s (25° C.) or less after 3 minutes from application.

11. The roll laminate according to claim 10, wherein the adhesive constituting the adhesive layer has a viscosity of 1×10⁶ mPa·s (25° C.) or less after 3 minutes from application.

12. A roll laminate comprising a long first metal foil and a long second metal foil that are bonded to each other via an adhesive layer, and are wound around a support, wherein the adhesive layer has a thickness of 1 μm or more in at least a part of the layer, and is provided along the longitudinal direction of the first and the second metal foil in at least both edge portions in the width of an overlapping region of the first and the second metal foil viewed in plan, and
wherein:
(a) one of the first metal foil and the second metal foil protrudes beyond the other metal foil at the both ends in the width of the roll laminate in a plan view of the first and the second metal foil;
(b) one of the first metal foil and the second metal foil protrudes beyond the other metal foil at one end of the roll laminate in the width direction, and the other metal foil protrudes beyond one of the first metal foil and the second foil at the other end of the roll laminate in the width direction in a plan view of the first and the second metal foil; or
(c) one of the first metal foil and the second metal foil protrudes beyond the other metal foil at one end of the roll laminate in the width direction, and the first and the second metal foil have aligned end portions at the other end of the roll laminate in the width direction in a plan view of the first and the second metal foil.

13. The roll laminate according to claim 12, which satisfies at least one of the following (1) to (9):
(1) the adhesive layer has a thickness of 300 μm or less;
(2) the adhesive layer has a width of 0.5 mm or more;
(3) the adhesive layer has a width of 100 mm or less;
(4) the first metal foil and the second metal foil each have a thickness of 5 to 70 μm;
(5) the adhesive layer is provided either continuously or discontinuously along the longitudinal direction of the first and the second metal foil;
(6) the roll laminate satisfies the formula 0≦d≦0.1×r, where d is the maximum depth of a gap created between the outermost surface of the roll laminate in the thickness direction of the first and the second metal foil, and a straight line drawn to connect the apices of bumps present on the outermost surface of the roll laminate in positions corresponding to the adhesive layers at both edge portions in the width of the first and the second metal foil, and r is the roll thickness of the roll laminate;
(7) the maximum depth (d) of the gap created between the straight line and the outermost surface of the roll laminate, and the roll thickness (r) of the roll laminate as defined in (6) satisfy the formula 0≦d≦0.05×r;
(8) the adhesive constituting the adhesive layer has a viscosity of 3×10⁶ mPa·s (25° C.) or less after 3 minutes from application; and
(9) the adhesive constituting the adhesive layer has a viscosity of 1×10⁶ mPa·s (25° C.) or less after 3 minutes from application.

14. A roll laminate comprising a long first metal foil and a long second metal foil that are bonded to each other via an adhesive layer, and are wound around a support,
wherein the adhesive layer has a thickness of 1 μm or more in at least a part of the layer, and is provided along the longitudinal direction of the first and the second metal foil in at least both edge portions in the width of an overlapping region of the first and the second metal foil viewed in plan, and
wherein:
the first metal foil is a carrier for a carrier-attached metal foil that includes the carrier, an interlayer, and an ultrathin metal layer, in this order, and
the second metal foil is the ultrathin metal layer for another carrier-attached metal foil that includes a carrier, an interlayer, and an ultrathin metal layer, in this order.

15. A roll laminate comprising a long first metal foil and a long second metal foil that are bonded to each other via an adhesive layer, and are wound around a support,
wherein the adhesive layer has a thickness of 1 μm or more in at least a part of the layer, and is provided along the longitudinal direction of the first and the second metal foil in at least both edge portions in the width of an overlapping region of the first and the second metal foil viewed in plan, and
wherein the first metal foil and the second metal foil each comprise a carrier-attached metal foil that includes a carrier, an interlayer, and an ultrathin metal layer, in this order.

16. The roll laminate according to claim 15, which satisfies at least one of the following (1) to (10):
(1) the adhesive layer has a thickness of 300 μm or less;
(2) the adhesive layer has a width of 0.5 mm or more;
(3) the adhesive layer has a width of 100 mm or less;
(4) the first metal foil and the second metal foil each have a thickness of 5 to 70 μm;
(5) the adhesive layer is provided either continuously or discontinuously along the longitudinal direction of the first and the second metal foil;
(6) the roll laminate satisfies the formula 0≦d≦0.1×r, where d is the maximum depth of a gap created between the outermost surface of the roll laminate in the thickness direction of the first and the second metal foil, and a straight line drawn to connect the apices of bumps present on the outermost surface of the roll laminate in positions corresponding to the adhesive layers at both edge portions in the width of the first and the second metal foil, and r is the roll thickness of the roll laminate;
(7) the maximum depth (d) of the gap created between the straight line and the outermost surface of the roll laminate, and the roll thickness (r) of the roll laminate as defined in
(6) satisfy the formula 0≦d≦0.05×r;
(8) the adhesive constituting the adhesive layer has a viscosity of 3×10⁶ mPa·s (25° C.) or less after 3 minutes from application;
(9) the adhesive constituting the adhesive layer has a viscosity of 1×10⁶ mPa·s (25° C.) or less after 3 minutes from application; and
(10)
(a) the first metal foil or the second metal foil protrudes beyond the other at the both ends in the width of the roll laminate in a plan view of the first and the second metal foil,
(b) the first metal foil or the second metal foil protrudes beyond the other at one end of the roll laminate in the width direction, and the other metal foil protrudes beyond the other at the other end of the roll laminate in the width direction in a plan view of the first and the second metal foil, or
(c) the first metal foil or the second metal foil protrudes beyond the other at one end of the roll laminate in the width direction, and the first and the second metal foil have aligned end portions at the other end of the roll laminate in the width direction in a plan view of the first and the second metal foil.

17. A method for producing a roll laminate,
the method comprising:
providing an adhesive layer along the longitudinal direction of a long first metal foil at both edge portions in the width of the first metal foil, wherein the first metal foil is not a metal foil that includes solely an insulating layer and a copper foil in this order on the surface opposite the surface provided with the adhesive layer;
bonding a long second metal foil to the adhesive layer-side surface of the first metal foil provided with the adhesive layer, wherein the second metal foil is not a metal foil that includes solely an insulating layer and a copper foil in this order on the surface opposite the surface bonded to the first metal foil; and
winding around a support the long first metal foil and the long second metal foil that are bonded to each other via the adhesive layer.

18. A method for producing a roll laminate,
the method comprising:
taking the first and the second metal foil from (i) a roll laminate comprising a long first metal foil and a long second metal foil that are bonded to each other via an adhesive layer, and are wound around a support, wherein the adhesive layer has a thickness of 1 μm or more in at least a part of the layer, and is provided along the longitudinal direction of the first and the second metal foil in at least both edge portions in the width of an overlapping region of the first and the second metal foil viewed in plan, or (ii) a roll laminate produced by the method of claim 17;
laminating a resin on at least one of the first metal foil and the second metal foil; and
winding the first metal foil, the second metal foil, and the resin around a support.

19. The method according to claim 18, wherein the roll laminate satisfies at least one of the following (1) to (12):
(1) the adhesive layer has a thickness of 300 μm or less;
(2) the adhesive layer has a width of 0.5 mm or more;
(3) the adhesive layer has a width of 100 mm or less;
(4) the first metal foil and the second metal foil each have a thickness of 5 to 70 μm;
(5) the adhesive layer is provided either continuously or discontinuously along the longitudinal direction of the first and the second metal foil;
(6) the roll laminate satisfies the formula 0≦d≦0.1×r, where d is the maximum depth of a gap created between the outermost surface of the roll laminate in the thickness direction of the first and the second metal foil, and a straight line drawn to connect the apices of bumps present on the outermost surface of the roll laminate in positions corresponding to the adhesive layers at both edge portions in the width of the first and the second metal foil, and r is the roll thickness of the roll laminate;
(7) the maximum depth (d) of the gap created between the straight line and the outermost surface of the roll laminate, and the roll thickness (r) of the roll laminate as defined in (6) satisfy the formula 0≦d≦0.05×r;
(8) the adhesive constituting the adhesive layer has a viscosity of 3×10⁶ mPa·s (25° C.) or less after 3 minutes from application;
(9) the adhesive constituting the adhesive layer has a viscosity of 1×10⁶ mPa·s (25° C.) or less after 3 minutes from application;
(10)
(a) the first metal foil or the second metal foil protrudes beyond the other at the both ends in the width of the roll laminate in a plan view of the first and the second metal foil,
(b) the first metal foil or the second metal foil protrudes beyond the other at one end of the roll laminate in the width direction, and the other metal foil protrudes beyond the other at the other end of the roll laminate in the width direction in a plan view of the first and the second metal foil, or
(c) the first metal foil or the second metal foil protrudes beyond the other at one end of the roll laminate in the width direction, and the first and the second metal foil have aligned end portions at the other end of the roll laminate in the width direction in a plan view of the first and the second metal foil;
(11) the first metal foil is a carrier for a carrier-attached metal foil that includes a carrier, an interlayer, and an ultrathin metal layer, in this order, and the second metal foil is the ultrathin metal layer; and
(12) the first metal foil and the second metal foil each comprise a carrier-attached metal foil that includes a carrier, an interlayer, and an ultrathin metal layer, in this order.

20. A method for producing a laminate,
the method comprising taking the first and the second metal foil from the roll laminate of claim 1 to produce a laminate that includes the first and the second metal foil.

21. A method for producing a laminate,
the method comprising taking the first and the second metal foil from the roll laminate of claim 7 to produce a laminate that includes the first and the second metal foil.

22. A method for producing a laminate,
the method comprising taking the first and the second metal foil from the roll laminate of claim 12 to produce a laminate that includes the first and the second metal foil.

23. A method for producing a laminate,
the method comprising taking the first and the second metal foil from the roll laminate of claim 15 to produce a laminate that includes the first and the second metal foil.

24. A method for producing a laminate,
the method comprising taking the first and the second metal foil from a roll laminate produced by the method of claim 17 to produce a laminate that includes the first and the second metal foil.

25. A method for producing a laminate,
the method comprising taking the first and the second metal foil from a roll laminate produced by the method of claim 18 to produce a laminate that includes the first and the second metal foil.

26. A method for producing a build-up substrate,
the method comprising:
forming one or more build-up wiring layers on at least one surface of a laminate produced by a method for producing a laminate that includes a first and a second metal foil by taking the first and the second metal foil from (i) a roll laminate comprising a long first metal foil and a long second metal foil that are bonded to each other via an adhesive layer, and are wound around a support, wherein the adhesive layer has a thickness of 1 μm or more in at least a part of the layer, and is provided along the longitudinal direction of the first and the second metal foil in at least both edge portions in the width of an overlapping region of the first and the second metal foil viewed in plan, or (ii) a roll laminate produced by the method of claim 17.

27. The method according to claim 26, wherein the roll laminate satisfies at least one of the following (1) to (12):
(1) the adhesive layer has a thickness of 300 μm or less;
(2) the adhesive layer has a width of 0.5 mm or more;
(3) the adhesive layer has a width of 100 mm or less;
(4) the first metal foil and the second metal foil each have a thickness of 5 to 70 μm;
(5) the adhesive layer is provided either continuously or discontinuously along the longitudinal direction of the first and the second metal foil;
(6) the roll laminate satisfies the formula 0≦d≦0.1×r, where d is the maximum depth of a gap created between the outermost surface of the roll laminate in the thickness direction of the first and the second metal foil, and a straight line drawn to connect the apices of bumps present on the outermost surface of the roll laminate in positions corresponding to the adhesive layers at both edge portions in the width of the first and the second metal foil, and r is the roll thickness of the roll laminate;
(7) the maximum depth (d) of the gap created between the straight line and the outermost surface of the roll laminate, and the roll thickness (r) of the roll laminate as defined in (6) satisfy the formula 0≦d≦0.05×r;
(8) the adhesive constituting the adhesive layer has a viscosity of 3×10⁶ mPa·s (25° C.) or less after 3 minutes from application;
(9) the adhesive constituting the adhesive layer has a viscosity of 1×10⁶ mPa·s (25° C.) or less after 3 minutes from application;
(10)
(a) the first metal foil or the second metal foil protrudes beyond the other at the both ends in the width of the roll laminate in a plan view of the first and the second metal foil,
(b) the first metal foil or the second metal foil protrudes beyond the other at one end of the roll laminate in the width direction, and the other metal foil protrudes beyond the other at the other end of the roll laminate in the width direction in a plan view of the first and the second metal foil, or
(c) the first metal foil or the second metal foil protrudes beyond the other at one end of the roll laminate in the width direction, and the first and the second metal foil have aligned end portions at the other end of the roll laminate in the width direction in a plan view of the first and the second metal foil;
(11) the first metal foil is a carrier for a carrier-attached metal foil that includes a carrier, an interlayer, and an ultrathin metal layer, in this order, and the second metal foil is the ultrathin metal layer; and
(12) the first metal foil and the second metal foil each comprise a carrier-attached metal foil that includes a carrier, an interlayer, and an ultrathin metal layer, in this order.

28. The method according to claim 26, wherein the build-up wiring layers are formed by using at least one of a subtractive method, a full-additive method, and a semi-additive method.

29. A method for producing a build-up substrate,
the method comprising:
laminating at least once a resin, a one-sided or double-sided wiring board, a one-sided or double-sided metal clad laminate, a laminate A, a resin substrate-attached metal layer, a carrier-attached metal layer, a wire, a circuit, or a metal layer on at least one surface of a laminate A produced by a method for producing a laminate A that includes a first and a second metal foil by taking the first and the second metal foil from (i) a roll laminate comprising a long first metal foil and a long second metal foil that are bonded to each other via an adhesive layer, and are wound around a support, wherein the adhesive layer has a thickness of 1 μm or more in at least a part of the layer, and is provided along the longitudinal direction of the first and the second metal foil in at least both edge portions in the width of an overlapping region of the first and the second metal foil viewed in plan, or (ii) a roll laminate produced by the method of claim 17.

30. The method according to claim 29, wherein the roll laminate satisfies at least one of the following (1) to (12):
(1) the adhesive layer has a thickness of 300 μm or less;
(2) the adhesive layer has a width of 0.5 mm or more;
(3) the adhesive layer has a width of 100 mm or less;
(4) the first metal foil and the second metal foil each have a thickness of 5 to 70 μm;
(5) the adhesive layer is provided either continuously or discontinuously along the longitudinal direction of the first and the second metal foil;
(6) the roll laminate satisfies the formula 0≦d≦0.1×r, where d is the maximum depth of a gap created between the outermost surface of the roll laminate in the thickness direction of the first and the second metal foil, and a straight line drawn to connect the apices of bumps present on the outermost surface of the roll laminate in positions corresponding to the adhesive layers at both edge portions in the width of the first and the second metal foil, and r is the roll thickness of the roll laminate;
(7) the maximum depth (d) of the gap created between the straight line and the outermost surface of the roll laminate, and the roll thickness (r) of the roll laminate as defined in (6) satisfy the formula 0≦d≦0.05×r;
(8) the adhesive constituting the adhesive layer has a viscosity of 3×10⁶ mPa·s (25° C.) or less after 3 minutes from application;
(9) the adhesive constituting the adhesive layer has a viscosity of 1×10⁶ mPa·s (25° C.) or less after 3 minutes from application;
(10)
(a) the first metal foil or the second metal foil protrudes beyond the other at the both ends in the width of the roll laminate in a plan view of the first and the second metal foil,
(b) the first metal foil or the second metal foil protrudes beyond the other at one end of the roll laminate in the width direction, and the other metal foil protrudes beyond the other at the other end of the roll laminate in the width direction in a plan view of the first and the second metal foil, or
(c) the first metal foil or the second metal foil protrudes beyond the other at one end of the roll laminate in the width direction, and the first and the second metal foil have aligned end portions at the other end of the roll laminate in the width direction in a plan view of the first and the second metal foil;
(11) the first metal foil is a carrier for a carrier-attached metal foil that includes a carrier, an interlayer, and an ultrathin metal layer, in this order, and the second metal foil is the ultrathin metal layer; and
(12) the first metal foil and the second metal foil each comprise a carrier-attached metal foil that includes a carrier, an interlayer, and an ultrathin metal layer, in this order.

31. The method according to claim 29, further comprising:
boring the resin, the one-sided or double-sided circuit board, the one-sided or double-sided metal clad laminate, the laminate A, the resin substrate-attached metal layer, the carrier-attached metal layer, the wire, the circuit, or the metal layer; and
subjecting a side surface and a bottom surface of the bore to conductive plating.

32. The method according to claim 29, further comprising:
forming a wire at least once on at least one of a metal layer constituting the one-sided or double-sided circuit board, a metal layer constituting the one-sided or double-sided metal clad laminate, a metal foil constituting the laminate A, a metal layer constituting the carrier-attached metal layer, a metal layer constituting the resin substrate-attached metal layer, and the metal layer.

33. The method according to claim 29, further comprising:
laminating, on a wired surface, a laminate produced by a method for producing a laminate that includes the first and the second metal foil by taking the first and the second metal foil from a roll laminate comprising a long first metal foil and a long second metal foil that are bonded to each other via an adhesive layer, and are wound around a support, wherein the adhesive layer has a thickness of 1 μm or more in at least a part of the layer, and is provided along the longitudinal direction of the first and the second metal foil in at least both edge portions in the width of an overlapping region of the first and the second metal foil viewed in plan.

34. The method according to claim 33, wherein the roll laminate satisfies at least one of the following (1) to (12):
(1) the adhesive layer has a thickness of 300 μm or less;
(2) the adhesive layer has a width of 0.5 mm or more;
(3) the adhesive layer has a width of 100 mm or less;
(4) the first metal foil and the second metal foil each have a thickness of 5 to 70 μm;
(5) the adhesive layer is provided either continuously or discontinuously along the longitudinal direction of the first and the second metal foil;
(6) the roll laminate satisfies the formula 0≦d≦0.1×r, where d is the maximum depth of a gap created between the outermost surface of the roll laminate in the thickness direction of the first and the second metal foil, and a straight line drawn to connect the apices of bumps present on the outermost surface of the roll laminate in positions corresponding to the adhesive layers at both edge portions in the width of the first and the second metal foil, and r is the roll thickness of the roll laminate;
(7) the maximum depth (d) of the gap created between the straight line and the outermost surface of the roll laminate, and the roll thickness (r) of the roll laminate as defined in (6) satisfy the formula 0≦d≦0.05×r;
(8) the adhesive constituting the adhesive layer has a viscosity of 3×10⁶ mPa·s (25° C.) or less after 3 minutes from application;
(9) the adhesive constituting the adhesive layer has a viscosity of 1×10⁶ mPa·s (25° C.) or less after 3 minutes from application;
(10)
(a) the first metal foil or the second metal foil protrudes beyond the other at the both ends in the width of the roll laminate in a plan view of the first and the second metal foil,
(b) the first metal foil or the second metal foil protrudes beyond the other at one end of the roll laminate in the width direction, and the other metal foil protrudes beyond the other at the other end of the roll laminate in the width direction in a plan view of the first and the second metal foil, or
(c) the first metal foil or the second metal foil protrudes beyond the other at one end of the roll laminate in the width direction, and the first and the second metal foil have aligned end portions at the other end of the roll laminate in the width direction in a plan view of the first and the second metal foil;
(11) the first metal foil is a carrier for a carrier-attached metal foil that includes a carrier, an interlayer, and an ultrathin metal layer, in this order, and the second metal foil is the ultrathin metal layer; and
(12) the first metal foil and the second metal foil each comprise a carrier-attached metal foil that includes a carrier, an interlayer, and an ultrathin metal layer, in this order.

35. The method according to claim 29, comprising:
cutting the laminate A at at least one laminated surface of the metal foils viewed in plan.

36. The method according to claim 35, further comprising:
detaching and separating the metal foils of the cut laminate from each other.

37. The method according to claim 36, further comprising:
removing the detached and separated metal foil either in part or as a whole by etching.

38. A method for producing a printed wiring board, wherein the method uses a laminate produced by a method for producing a laminate that includes the first and the second metal foil by taking the first and the second metal foil from a roll laminate produced by the method of claim 17.

39. A method for producing a printed wiring board using a build-up substrate produced by the method of claim 26.

40. The method according to claim 38, wherein the roll laminate satisfies at least one of the following (1) to (12):
(1) the adhesive layer has a thickness of 300 μm or less;
(2) the adhesive layer has a width of 0.5 mm or more;
(3) the adhesive layer has a width of 100 mm or less;
(4) the first metal foil and the second metal foil each have a thickness of 5 to 70 μm;
(5) the adhesive layer is provided either continuously or discontinuously along the longitudinal direction of the first and the second metal foil;
(6) the roll laminate satisfies the formula 0≦d≦0.1×r, where d is the maximum depth of a gap created between the outermost surface of the roll laminate in the thickness direction of the first and the second metal foil, and a straight line drawn to connect the apices of bumps present on the outermost surface of the roll laminate in positions corresponding to the adhesive layers at both edge portions in the width of the first and the second metal foil, and r is the roll thickness of the roll laminate;
(7) the maximum depth (d) of the gap created between the straight line and the outermost surface of the roll laminate, and the roll thickness (r) of the roll laminate as defined in (6) satisfy the formula 0≦d≦0.05×r;
(8) the adhesive constituting the adhesive layer has a viscosity of 3×10⁶ mPa·s (25° C.) or less after 3 minutes from application;
(9) the adhesive constituting the adhesive layer has a viscosity of 1×10⁶ mPa·s (25° C.) or less after 3 minutes from application;
(10)
(a) the first metal foil or the second metal foil protrudes beyond the other at the both ends in the width of the roll laminate in a plan view of the first and the second metal foil,
(b) the first metal foil or the second metal foil protrudes beyond the other at one end of the roll laminate in the width direction, and the other metal foil protrudes beyond the other at the other end of the roll laminate in the width direction in a plan view of the first and the second metal foil, or
(c) the first metal foil or the second metal foil protrudes beyond the other at one end of the roll laminate in the width direction, and the first and the second metal foil have aligned end portions at the other end of the roll laminate in the width direction in a plan view of the first and the second metal foil;
(11) the first metal foil is a carrier for a carrier-attached metal foil that includes a carrier, an interlayer, and an ultrathin metal layer, in this order, and the second metal foil is the ultrathin metal layer; and
(12) the first metal foil and the second metal foil each comprise a carrier-attached metal foil that includes a carrier, an interlayer, and an ultrathin metal layer, in this order.

41. A method for producing an electronic device using a printed wiring board produced by the method of claim 38.

42. A method for producing an electronic device using a printed wiring board produced by the method of claim 39.
